(19) United States
(12) Patent Application Publication
(10) Pub. No.: US 2026/0297805 A1
(43) Pub. Date: Oct. 1, 2026

(54) GALLIUM BASE SUBSTRATE, GALLIUM NITRIDE GROWTH SUBSTRATE, AND MANUFACTURING METHOD OF GALLIUM NITRIDE BASE SUBSTRATE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); National University Corporation Tokai National Higher Education and Research System, Nagoya-shi (JP)

(72) Inventors: Shinichi HOSHI, Nisshin-shi (JP); Jun KOJIMA, Nisshin-shi (JP); Atsushi TANAKA, Nagoya-shi (JP); Kenji ISO, Tokyo (JP)

(21) Appl. No.: 19/573,598

(22) Filed: Mar. 20, 2026

(30) Foreign Application Priority Data
Mar. 31, 2025 (JP) 2025-058683

(51) Int. Cl. C30B 25/18; C30B 25/20; C30B 29/40; C30B 33/04

(52) U.S. Cl. CPC C30B 25/186; C30B 25/20; C30B 29/406; C30B 33/04

(57) ABSTRACT

A gallium nitride base substrate includes a support substrate including aluminum nitride or ScAlMgO₄, and a gallium nitride thin-film substrate including gallium nitride, disposed above the support substrate, and surface-activated bonded to the support substrate. A stoichiometric ratio of the gallium nitride thin-film substrate is uniform throughout an entire region of the gallium nitride thin-film substrate.

### CROSS REFERENCE TO RELATED APPLICATION

The present application claims the benefit of priority from Japanese Patent Application No. 2025-058683 filed on Mar. 31, 2025. The entire disclosure of the above application is incorporated herein by reference.

### TECHNICAL FIELD

The present disclosure relates to a gallium nitride base substrate, a gallium nitride growth substrate, and a manufacturing method of a gallium nitride base substrate.

### BACKGROUND

It has been proposed to form a gallium nitride (GaN) base substrate by bonding a silicon thin-film substrate to a support substrate, and to grow an epitaxial layer including GaN on the silicon thin-film substrate of the GaN base substrate.

### SUMMARY

A gallium nitride base substrate according to an aspect of the present disclosure includes a support substrate including aluminum nitride or ScAlMgO₄, and a gallium nitride thin-film substrate including gallium nitride, disposed above the support substrate, and surface-activated bonded to the support substrate. A stoichiometric ratio of the gallium nitride thin-film substrate is uniform throughout an entire region of the gallium nitride thin-film substrate.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a GaN base substrate according to a first embodiment;

FIG. 2 is a cross-sectional view of a GaN growth substrate according to the first embodiment;

FIG. 3A is a cross-sectional view showing a manufacturing process of the GaN base substrate illustrated in FIG. 1;

FIG. 3B is a cross-sectional view showing a subsequent manufacturing process of the GaN base substrate following FIG. 3A;

FIG. 3C is a cross-sectional view showing a subsequent manufacturing process of the GaN base substrate following FIG. 3B;

FIG. 3D is a cross-sectional view showing a subsequent manufacturing process of the GaN base substrate following FIG. 3C;

FIG. 3E is a cross-sectional view showing a subsequent manufacturing process of the GaN base substrate following FIG. 3D;

FIG. 3F is a cross-sectional view showing a subsequent manufacturing process of the GaN base substrate following FIG. 3E;

FIG. 3G is a cross-sectional view showing a subsequent manufacturing process of the GaN base substrate following FIG. 3F;

FIG. 3H is a cross-sectional view of a GaN growth substrate in which an epitaxial layer has been grown on the GaN base substrate;

FIG. 4 is a cross-sectional view of a GaN base substrate according to a second embodiment;

FIG. 5 is a cross-sectional view of a GaN base substrate according to a third embodiment; and

FIG. 6 is a cross-sectional view of a GaN base substrate according to a fourth embodiment.

### DETAILED DESCRIPTION

In a GaN base substrate, a silicon thin-film substrate may be prepared as follows. First, an ingot composed of silicon is prepared. Then, ion implantation is performed on the ingot to form a brittle layer, and the ingot is divided starting from the brittle layer, thereby preparing the silicon thin-film substrate.

When ion implantation is performed on the ingot to form the brittle layer, because the ions are implanted in a Gaussian distribution, damage such as disruption of crystallinity is also introduced into portions other than the brittle layer. Therefore, the silicon thin-film substrate is subjected, for example, to heat treatment at around 1000°C to reduce the damage caused by ion implantation.

Then, by growing a GaN-containing epitaxial layer on the GaN base substrate having the silicon thin-film substrate in which the damage has been reduced, an epitaxial layer with crystal defects (hereinafter simply referred to as “defects”) equivalent to those in a GaN-containing epitaxial layer grown on a silicon substrate is formed. When the silicon thin-film substrate has a main surface (that is, a surface on which epitaxial growth is performed) that is an Si(111) plane, the lattice constant mismatch with GaN becomes 17%. When GaN is epitaxially grown on such a silicon thin-film substrate, the defect density, such as dislocations, in the epitaxial layer is about 1.0×10⁹ cm⁻². Furthermore, when a GaN-containing epitaxial layer is grown using a silicon thin-film substrate whose main surface is a plane other than the (111) plane, the lattice constant mismatch between the silicon thin-film substrate and GaN becomes greater than 17%, resulting in an increased defect density in the epitaxial layer. Therefore, when growing a GaN-containing epitaxial layer on a silicon thin-film substrate in this manner, a Si(111) substrate is used as the silicon thin-film substrate.

Meanwhile, the present inventors are also investigating methods to further reduce defects in an epitaxial layer by bonding a GaN thin-film substrate to a support substrate to produce a GaN base substrate, and by growing a GaN-containing epitaxial layer on the GaN base substrate to produce a GaN growth substrate. However, similar to the above-described silicon thin-film substrate, if a GaN ingot is subjected to ion implantation to form a GaN thin-film substrate and then heat treatment is performed in order to reduce the damage, there is a possibility that GaN may decompose or the like and lose its stoichiometric balance. When reducing the damage of GaN, a heat treatment temperature is approximately 1000 to 1400°C. However, nitrogen loss may occur in GaN even at 800°C. Therefore, it is difficult to directly apply the manufacturing method for silicon thin-film substrates as is.

According to one aspect of the present disclosure, a gallium nitride base substrate includes a support substrate including aluminum nitride or ScAlMgO₄, and a gallium nitride thin-film substrate including gallium nitride, disposed above the support substrate, and surface-activated bonded to the support substrate. A stoichiometric ratio of the gallium nitride thin-film substrate is uniform throughout an entire region of the gallium nitride thin-film substrate.

According to this aspect, the gallium nitride base substrate is configured such that the GaN thin-film substrate is bonded above the support substrate. In addition, the GaN thin-film substrate has a stoichiometric ratio that is uniform throughout its entire region. Therefore, by growing an epitaxial layer on the gallium nitride base substrate, defects in the epitaxial layer can be reduced.

According to another aspect of the present disclosure, a gallium nitride growth substrate includes a gallium nitride base substrate and an epitaxial layer including gallium nitride and disposed above the gallium nitride base substrate. The gallium nitride base substrate includes a support substrate including aluminum nitride or ScAlMgO₄, and a gallium nitride thin-film substrate including gallium nitride, disposed above the support substrate, and surface-activated bonded to the support substrate. A stoichiometric ratio of the gallium nitride thin-film substrate is uniform throughout an entire region of the gallium nitride thin-film substrate.

According to this aspect, since the epitaxial layer is disposed above the gallium nitride base substrate, defects can be reduced.

According to another aspect of the present disclosure, a manufacturing method of a gallium nitride base substrate includes preparing a support substrate including aluminum nitride or ScAlMgO₄, preparing an ingot including gallium nitride, irradiating an interior of the ingot with laser light to form an altered layer along an in-plane direction of the ingot, dividing the ingot at the altered layer as a boundary to form a gallium nitride thin-film substrate from the ingot, and bonding the support substrate and the gallium nitride thin-film substrate by surface-activated bonding.

According to this aspect, the GaN base substrate is configured such that the GaN thin-film substrate is bonded onto the support substrate. In addition, since the GaN thin-film substrate is prepared by irradiating the ingot with laser light, the stoichiometric ratio is made uniform throughout the entire region. Therefore, by growing an epitaxial layer on the GaN base substrate, defects in the epitaxial layer can be reduced.

Embodiments of the present disclosure will be described below with reference to the drawings. In the following embodiments, the same reference numerals are assigned to parts that are the same or equivalent to each other.

### First Embodiment

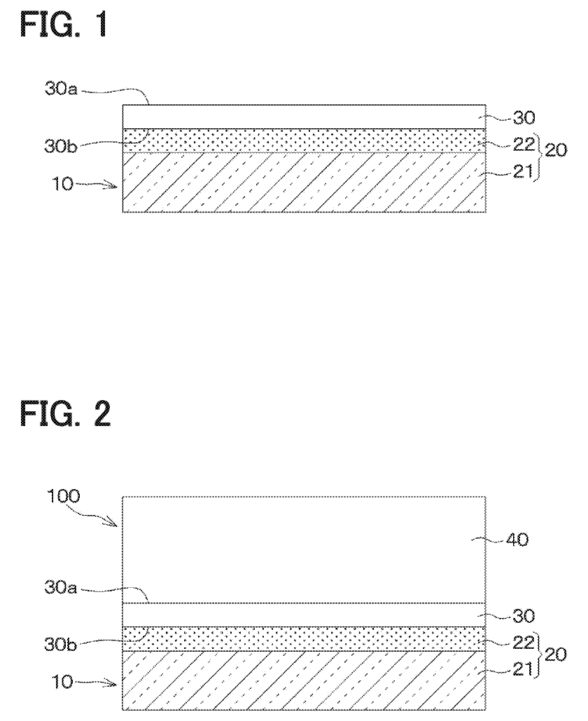

A first embodiment will be described with reference to the drawings. As shown in FIG. 1, a GaN base substrate 10 of the present embodiment includes a support substrate 20 and a GaN thin-film substrate 30. It should be noted that the GaN base substrate 10 has a cylindrical wafer shape.

In the present embodiment, the support substrate 20 includes a core layer 21 and a design layer 22 disposed on the core layer 21. The core layer 21 is intended to make the thermal expansion coefficient of the support substrate 20 closer to that of GaN. In the present embodiment, the core layer 21 is composed of a material such as AlN (aluminum nitride), which has a thermal expansion coefficient similar to that of GaN. The design layer 22 serves to absorb surface irregularities of the core layer 21 and to planarize a surface opposite to the core layer 21. In the present embodiment, the design layer 22 is composed of an oxide film.

As will be described later, the GaN thin-film substrate 30 is obtained by dividing an ingot composed of GaN. The GaN thin-film substrate 30 has a plate shape with a first surface 30a and a second surface 30b. In addition, the GaN thin-film substrate 30 of the present embodiment has a uniform stoichiometric ratio throughout the entire region of the GaN thin-film substrate 30. The second surface 30b of the GaN thin-film substrate 30 is connected to the design layer 22 of the support substrate 20 by means of surface-activated bonding. Here, the phrase “the stoichiometric ratio is uniform throughout the entire region of the GaN thin-film substrate 30” means that no crystal dislocations have occurred in any region. The thickness of the GaN thin-film substrate 30 is not particularly limited, but is, for example, about 1 to 20 μm. In the present embodiment, the first surface 30a of the GaN thin-film substrate 30 is a gallium face, while the second surface 30b is a nitrogen face.

The above describes the configuration of the GaN base substrate 10 in the present embodiment. As shown in FIG. 2, a GaN growth substrate 100 is configured by laminating an epitaxial layer 40 containing GaN on the GaN thin-film substrate 30. Since the GaN growth substrate 100 has the epitaxial layer 40 containing GaN disposed on the GaN thin-film substrate 30, the difference in lattice constant becomes smaller compared to the case where the epitaxial layer 40 is disposed on, for example, a silicon layer, and the defect density of the epitaxial layer 40 can be reduced to 1.0×10⁴ cm⁻² or less.

The GaN growth substrate 100 is used, for example, by being divided into individual chips to constitute semiconductor devices. When configuring a semiconductor device using the GaN growth substrate 100, for example, the epitaxial layer 40 may be formed by laminating an undoped GaN layer and an undoped AlGaN layer disposed on top of the GaN layer. In such an epitaxial layer 40, a two-dimensional electron gas layer is induced on the GaN layer side of the AlGaN/GaN interface by the piezoelectric effect and spontaneous polarization effect. Therefore, the GaN growth substrate 100 is used, for example, to construct a semiconductor device having a high electron mobility transistor (HEMT) that utilizes the two-dimensional electron gas layer. When a semiconductor device having a HEMT is constructed using the GaN growth substrate 100 of the present embodiment, the defect density of the epitaxial layer 40 can be reduced as described above, making it possible, for example, to reduce current collapse. It should be noted that current collapse is a phenomenon specific to the case where a HEMT is formed on GaN, and refers to an increase in on-resistance during operation, which is said to be caused by defects.

In addition, the GaN growth substrate 100 can be used, for example, to manufacture the GaN thin-film substrate 30, as will be described later.

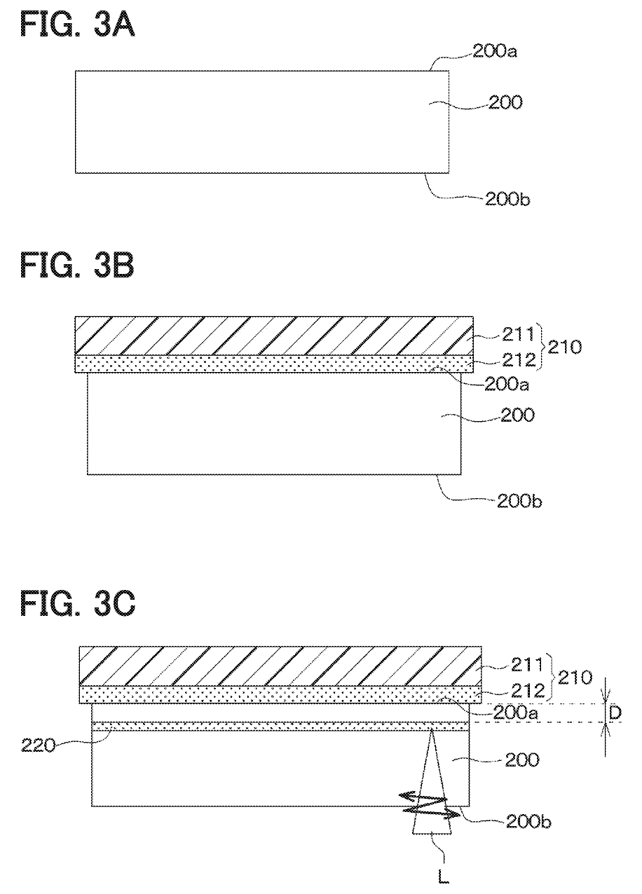

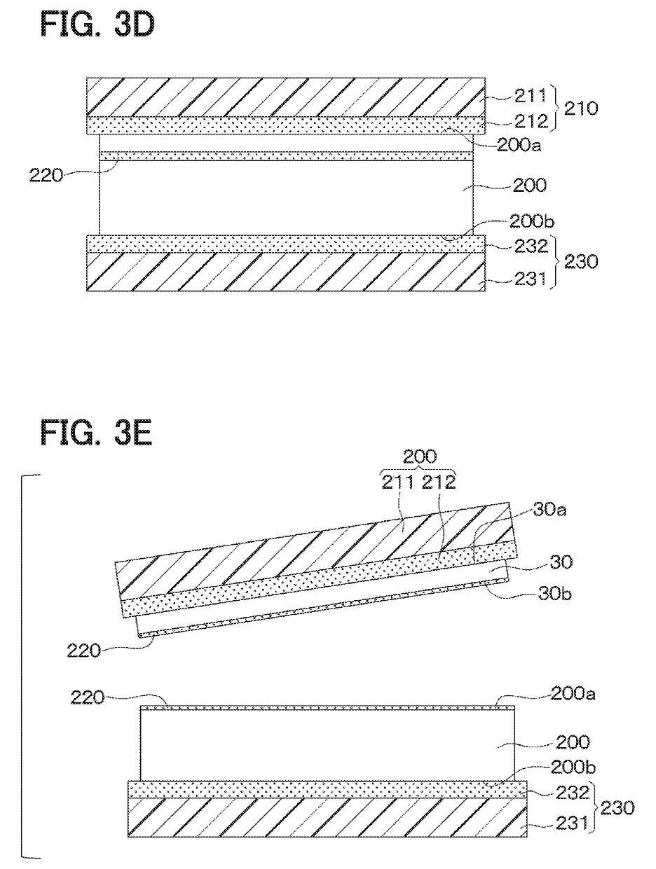

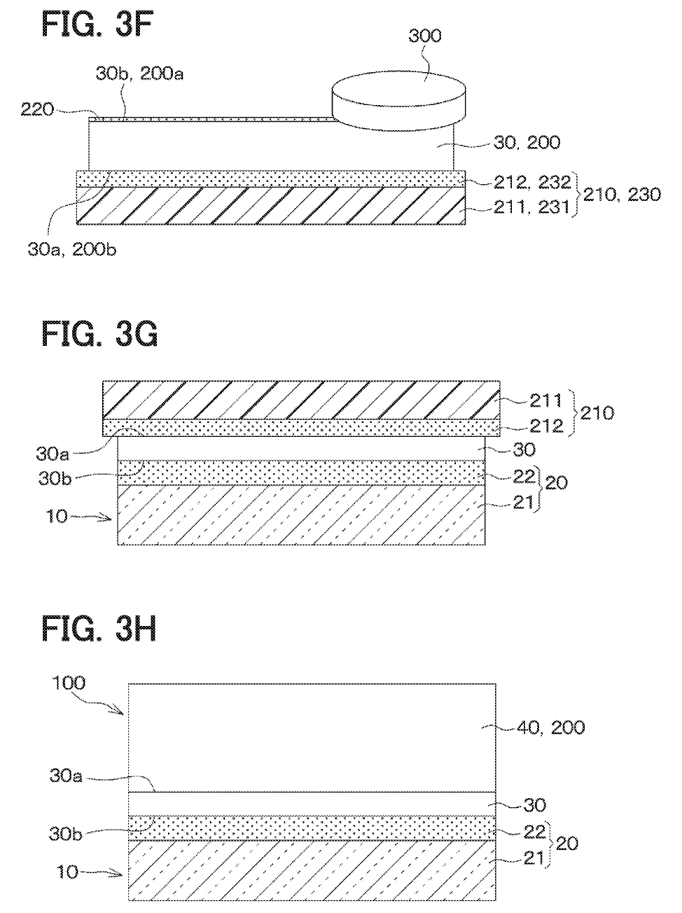

Next, a manufacturing method of the GaN base substrate 10 and the GaN growth substrate 100 will be described with reference to FIGS. 3A to 3H.

First, as shown in FIG. 3A, an ingot 200 composed of GaN and having a first main surface 200a and a second main surface 200b is prepared. The ingot 200 is, for example, produced by an ammonothermal method. The ingot 200 has a thickness of about 3 mm. In addition, in the ingot 200 of the present embodiment, the first main surface 200a is a gallium face and the second main surface 200b is a nitrogen face.

Next, as shown in FIG. 3B, a first holding member 210 is disposed on the first main surface 200a of the ingot 200. The first holding member 210 may be, for example, a dicing tape or the like having a base member 211 and an adhesive 212. The base member 211 is made of a material that is resistant to warping during the manufacturing process, and is composed, for example, of glass, a silicon substrate, ceramics, or the like. The adhesive 212 is made of a material whose adhesive strength can be varied, and is composed, for example, of an ultraviolet-curable resin whose adhesiveness changes with temperature or light, wax, double-sided tape, or the like.

Subsequently, as shown in FIG. 3C, laser light L is irradiated from the second main surface 200b of the ingot 200, and an altered layer 220 extending along an in-plane direction of the ingot 200 is formed at a position that is a predetermined depth D from the first main surface 200a of the ingot 200. In the present embodiment, in this process, a laser device having, for example, a laser light source, a spatial optical modulator, a condenser lens, and a displaceable stage is prepared. The laser light source oscillates the laser light L. The spatial optical modulator modulates the laser light L output from the laser light source. The condenser lens condenses the laser light L modulated by the spatial optical modulator. The spatial optical modulator includes, for example, liquid crystal on silicon (LCOS). The predetermined depth D is set according to factors such as the thickness of the GaN thin-film substrate 30 and allowance for grinding, and is, for example, set to 30 μm.

When forming the altered layer 220, the ingot 200 is placed on a stage, and the position of the stage is adjusted so that the focal point of the laser light L is relatively scanned along the in-plane direction of the ingot 200. As a result, at the portion irradiated with the laser light L, the altered layer 220 is formed in which gallium and nitrogen have been decomposed by thermal energy. More specifically, by irradiating the laser light L, nitrogen evaporates as gas and gallium precipitates, thereby forming the altered layer 220 in which cracks have occurred. When the altered layer 220 is formed by irradiating the laser light L in this manner, the crystallinity of the portions of the ingot 200 other than the portion where the altered layer 220 is formed remains intact.

Next, as shown in FIG. 3D, a second holding member 230 is disposed on the second main surface 200b of the ingot 200. The second holding member 230 is composed of, for example, a base member 231 and an adhesive 232 whose adhesive strength can be varied, similar to the first holding member 210. The base member 231 of the second holding member 230 is composed of, for example, glass, a silicon substrate, ceramics, or the like. The adhesive 232 of the second holding member 230 is composed of, for example, ultraviolet-curable resin, wax, double-sided tape, or the like.

Then, as shown in FIG. 3E, the first holding member 210 and the second holding member 230 are gripped, and a tensile force or the like is applied in the thickness direction of the ingot 200, thereby dividing the ingot 200 with the altered layer 220 as a starting point of separation. Then, one of the divided portions is used as the GaN thin-film substrate 30. In the present embodiment, the portion supported by the first holding member 210 is used as the GaN thin-film substrate 30. In addition, since the GaN thin-film substrate 30 is formed by irradiating the ingot 200 with laser light L as described above, the stoichiometric ratio is made uniform throughout the entire region.

Hereinafter, a surface of the ingot 200 from which the GaN thin-film substrate 30 has been separated will be referred to as a first main surface 200a of a new ingot 200. In addition, the surface of the GaN thin-film substrate 30 that has been separated from the ingot 200 is referred to as the second surface 30b of the GaN thin-film substrate 30, and the surface of the GaN thin-film substrate 30 that is held by the first holding member 210 is referred to as the first surface 30a of the GaN thin-film substrate 30.

Thereafter, as shown in FIG. 3F, a chemical mechanical polishing (CMP) method is performed using a polishing device 300 or the like on the first main surface 200a of the ingot 200 and the second surface 30b of the GaN thin-film substrate 30, thereby planarizing the first main surface 200a and the second surface 30b. In the present embodiment, for example, approximately 20 μm is removed by the CMP method. As a result, the GaN thin-film substrate 30 having a thickness of approximately 10 μm is prepared. In the present embodiment, in this manner, the GaN thin-film substrate 30 is prepared from the ingot 200. In addition, the ingot 200 with the first main surface 200a planarized is used again for the processes starting from FIG. 3A onward.

Next, as shown in FIG. 3G, the support substrate 20 is prepared in which the design layer 22 is disposed on the core layer 21, and the design layer 22 of the support substrate 20 and the second surface 30b of the GaN thin-film substrate 30 are bonded together by surface-activated bonding. In the present embodiment, in this way, the GaN base substrate 10 is manufactured. It should be noted that, in the present embodiment, since the first main surface 200a of the ingot 200 is a gallium face, the first surface 30a of the GaN thin-film substrate 30 becomes a gallium face.

Then, as shown in FIG. 3H, the epitaxial layer 40 including GaN is epitaxially grown on the GaN thin-film substrate 30 of the GaN base substrate 10 by performing a halide vapor phase epitaxy (HVPE) method or the like at a temperature of 1000 to 1200°C. As a result, the GaN growth substrate 100 in which the epitaxial layer 40 is disposed on the GaN base substrate 10 is formed.

The GaN growth substrate 100 can be used, for example, by utilizing a portion of the epitaxial layer 40 as the ingot 200 in the process shown in FIG. 3A. Therefore, after the GaN growth substrate 100 has been manufactured, it becomes possible to mass-produce the GaN base substrate 10 without the need to prepare a new ingot 200. When using the GaN growth substrate 100 as the ingot 200, the thickness of the epitaxial layer 40 can be increased to the extent that warping of the GaN growth substrate 100 does not occur. For example, the epitaxial layer 40 can be formed to a thickness of about 100 to 1000 μm.

In addition, the GaN growth substrate 100 can be used for manufacturing semiconductor devices having, for example, a HEMT, by appropriately adjusting the structure of the epitaxial layer 40 as needed. In this case, the thickness of the epitaxial layer 40 is appropriately designed according to the required breakdown voltage and other specifications.

According to the present embodiment described above, the GaN base substrate 10 is configured by bonding the GaN thin-film substrate 30 onto the support substrate 20. In addition, since the GaN thin-film substrate 30 is prepared by irradiating the ingot 200 with laser light L, the stoichiometric ratio is made uniform throughout the entire region of the GaN thin-film substrate 30. Therefore, by growing the epitaxial layer 40 on the GaN base substrate 10 described above, defects in the epitaxial layer 40 can be reduced.

### Second Embodiment

The following describes a second embodiment of the present disclosure. The present embodiment differs from the first embodiment in that the configuration of the support substrate 20 has been modified. The other configurations of the present embodiment are similar to those of the first embodiment, and therefore a description of the similar configurations will be omitted.

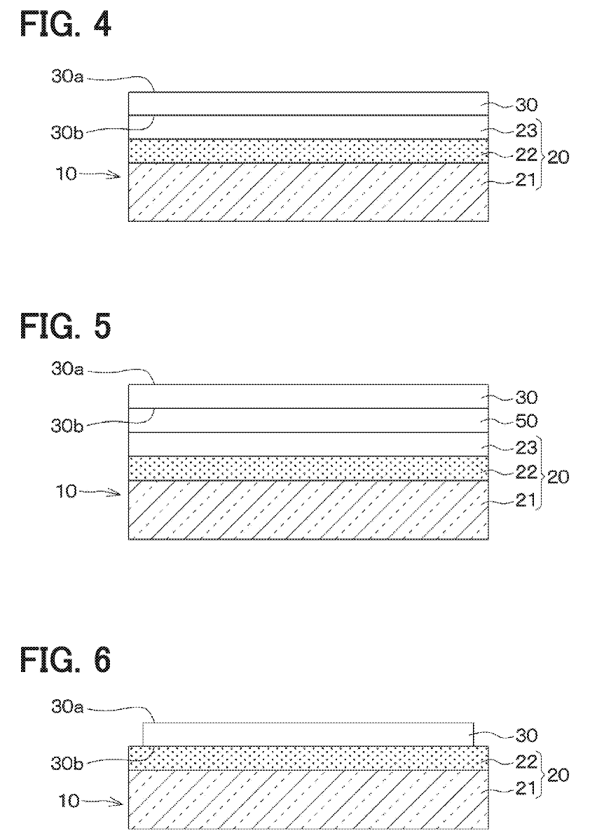

As shown in FIG. 4, the GaN base substrate 10 of the present embodiment is configured such that the support substrate 20 includes a core layer 21, a design layer 22, and a silicon layer 23. In other words, the support substrate 20 of the present embodiment is a so-called QST (an abbreviation for Qromis Substrate Technology; registered trademark) substrate. The silicon layer 23 is Si(111), in which a main surface (that is, a surface bonded with the GaN thin-film substrate 30) is the (111) plane, and has a thickness of about 0.3 to 3.0 μm. The GaN thin-film substrate 30 is connected to the silicon layer 23 of the support substrate 20 by means of surface-activated bonding, with the second surface 30b joined to the silicon layer 23. In the present embodiment, the silicon layer 23 corresponds to a bonding layer.

According to the present embodiment described above, the GaN base substrate 10 is formed by bonding the GaN thin-film substrate 30 onto the support substrate 20, and the GaN thin-film substrate 30 has a stoichiometric ratio that is made uniform throughout the entire region of the GaN thin-film substrate 30. Therefore, effects similar to those of the first embodiment can be obtained.

In the present embodiment, the support substrate 20 is configured as the QST substrate. Therefore, an existing substrate can be used as the support substrate 20, thereby simplifying the manufacturing process. Furthermore, since the support substrate 20 has the silicon layer 23, when configuring a semiconductor device using the GaN growth substrate 100, it is also possible to form semiconductor elements on the silicon layer 23. For example, when configuring a semiconductor device using the GaN growth substrate 100, by forming a diode on the silicon layer 23 and forming a HEMT using the epitaxial layer 40, it is possible to obtain a semiconductor device with improved avalanche capability. It should be noted that, in the present embodiment, an example in which the silicon layer 23 is Si(111) has been described, but the crystal orientation of the silicon layer 23 can be changed as appropriate.

### Third Embodiment

The following describes a third embodiment of the present disclosure. In the present embodiment, compared to the second embodiment, a barrier layer is provided between the silicon layer 23 of the support substrate 20 and the GaN thin-film substrate 30. The other configurations of the present embodiment are similar to those of the second embodiment, and therefore a description of the similar configurations will not be repeated.

As shown in FIG. 5, the GaN base substrate 10 of the present embodiment is provided with a barrier layer 50 between the silicon layer 23 of the support substrate 20 and the GaN thin-film substrate 30. Then, the GaN thin-film substrate 30 is bonded to the barrier layer 50 by surface-activated bonding. The barrier layer 50 is intended to prevent Ga of the GaN thin-film substrate 30 and the silicon layer 23 from reacting with each other during the growth of the epitaxial layer 40, and is formed of a material having a melting point of 1500°C or higher. For example, the barrier layer 50 may be formed of a high melting point metal such as tungsten (W) or tantalum (Ta). The barrier layer 50 may be formed of a polycrystalline film or a single-crystal film such as aluminum nitride (AlN). The barrier layer 50 may be formed of a single-crystal film such as silicon carbide (SiC) and aluminum oxide (Al₂O₃). Then, the barrier layer 50 composed of such materials is, for example, formed on the silicon layer 23 by a sputtering method or the like. However, it is preferable that the barrier layer 50 is formed of a material with a small difference in thermal expansion coefficient from the GaN thin-film substrate 30 or the epitaxial layer 40. For example, the barrier layer 50 is preferably formed of a single-crystal AlN film.

According to the present embodiment described above, the GaN base substrate 10 is formed by bonding the GaN thin-film substrate 30 onto the support substrate 20, and the GaN thin-film substrate 30 has a stoichiometric ratio that is made uniform throughout the entire region of the GaN thin-film substrate 30. Therefore, the same effects as those of the first embodiment described above can be obtained.

In the present embodiment, the barrier layer 50 formed of a material having a melting point of 1500°C or higher is disposed between the silicon layer 23 of the support substrate 20 and the GaN thin-film substrate 30. Therefore, it is possible to suppress the reaction between the Ga in the GaN thin-film substrate 30 and the silicon layer 23. Accordingly, it is possible to prevent deterioration in the quality of the epitaxial layer 40. Furthermore, when forming a semiconductor device on the silicon layer 23, it is possible to suppress changes in the characteristics of the semiconductor device.

### Fourth Embodiment

The following describes a fourth embodiment. The present embodiment differs from the first embodiment in that the configuration of the GaN thin-film substrate 30 has been changed. The other configurations of the present embodiment are similar to those of the first embodiment, and therefore a description of the similar configurations will be omitted.

As shown in FIG. 6, in the GaN base substrate 10 of the present embodiment, when viewed in the stacking direction of the support substrate 20 and the GaN thin-film substrate 30, the outer edge portion of the support substrate 20 protrudes beyond the GaN thin-film substrate 30. That is, the GaN thin-film substrate 30 has a diameter smaller than that of the support substrate 20.

The GaN base substrate 10 is manufactured by using the epitaxial layer 40 of the GaN growth substrate 100 described in the first embodiment as the ingot 200. That is, when the epitaxial layer 40 is grown on the GaN base substrate 10 to form the GaN growth substrate 100, the diameter of the epitaxial layer 40 does not remain constant along the thickness direction, but instead decreases toward the side opposite to the GaN base substrate 10. Therefore, when the epitaxial layer 40 of the GaN growth substrate 100 is used as the ingot 200 to manufacture the GaN thin-film substrate 30, the diameter of the GaN thin-film substrate 30 becomes smaller than that of the support substrate 20.

According to the present embodiment described above, the GaN base substrate 10 is formed by bonding the GaN thin-film substrate 30 onto the support substrate 20, and the GaN thin-film substrate 30 has a stoichiometric ratio that is made uniform throughout the entire region of the GaN thin-film substrate 30. Therefore, the same effects as those of the first embodiment described above can be obtained.

In the present embodiment, an outer edge portion of the support substrate 20 protrudes beyond the GaN thin-film substrate 30. The GaN base substrate 10 is manufactured by using the epitaxial layer 40 of the GaN growth substrate 100 as the ingot 200. Therefore, compared to the case where the GaN base substrate 10 is manufactured using the ingot 200 produced by an ammonothermal method or the like, it becomes easier to accommodate mass production and cost reduction can be achieved.

### Other Embodiments

Although the present disclosure has been described in accordance with the embodiments, it is understood that the present disclosure is not limited to such embodiments or structures. The present disclosure encompasses various modifications and variations within the scope of equivalents. Furthermore, various combinations and formations, and other combinations and formations including one, more than one or less than one element may be made in the present disclosure.

In each of the above-described embodiments, examples have been described in which the support substrate 20 includes the design layer 22 disposed on the core layer 21. However, the support substrate 20 may not necessarily include the design layer 22.

In addition, in each of the above-described embodiments, examples have been described in which the support substrate 20 includes the core layer 21 including AlN. However, the support substrate 20 may also be configured to include ScAlMgO₄ (that is, a so-called SAM substrate). In this case, the support substrate 20 may be provided with the design layer 22, or the support substrate 20 may not include the design layer 22. Additionally, the support substrate 20 may include the silicon layer 23, as in the second embodiment described above. It should be noted that ScAlMgO₄ has a difference in coefficient of thermal expansion from GaN of about 0.6%, and thus has substantially the same coefficient of thermal expansion as GaN. In addition, the lattice-constant mismatch rate of ScAlMgO₄ is about 1.8%, meaning that ScAlMgO₄ is a material having lattice constants substantially the same as those of GaN.

In the second embodiment described above, an example has been described in which the support substrate 20 includes the silicon layer 23 disposed on the design layer 22. However, instead of the silicon layer 23 being disposed on the design layer 22, a polysilicon layer or an amorphous silicon layer or the like may be disposed on the design layer 22. In this case, the polysilicon layer or the amorphous silicon layer corresponds to the bonding layer. In other words, the structure of the bonding layer can be appropriately modified according to the application.

In addition, each of the above-described embodiments can be combined as appropriate. For example, the fourth embodiment described above may be combined with the second or third embodiment.

What is claimed is:

1. A gallium nitride base substrate comprising:
a support substrate including aluminum nitride or ScAlMgO₄; and
a gallium nitride thin-film substrate including gallium nitride, disposed above the support substrate, and surface-activated bonded to the support substrate, wherein
a stoichiometric ratio of the gallium nitride thin-film substrate is uniform throughout an entire region of the gallium nitride thin-film substrate.

2. The gallium nitride base substrate according to claim 1, wherein
the support substrate has a bonding layer on a side facing the gallium nitride thin-film substrate.

3. The gallium nitride base substrate according to claim 2, further comprising
a barrier layer formed of a material having a melting point of 1500°C or higher and disposed between the bonding layer and the gallium nitride thin-film substrate, wherein
the bonding layer is a silicon layer.

4. The gallium nitride base substrate according to claim 1, wherein
an outer edge portion of the support substrate protrudes beyond the gallium nitride thin-film substrate when viewed in a stacking direction of the support substrate and the gallium nitride thin-film substrate.

5. A gallium nitride growth substrate comprising:
a gallium nitride base substrate; and
an epitaxial layer including gallium nitride and disposed above the gallium nitride base substrate, wherein
the gallium nitride base substrate includes:
a support substrate including aluminum nitride or ScAlMgO₄; and
a gallium nitride thin-film substrate including gallium nitride, disposed above the support substrate, and surface-activated bonded to the support substrate, and
a stoichiometric ratio of the gallium nitride thin-film substrate is uniform throughout an entire region of the gallium nitride thin-film substrate.

6. A manufacturing method of a gallium nitride base substrate, comprising:
preparing a support substrate including aluminum nitride or ScAlMgO₄;
preparing an ingot including gallium nitride;
irradiating an interior of the ingot with laser light to form an altered layer along an in-plane direction of the ingot;
dividing the ingot at the altered layer as a boundary to form a gallium nitride thin-film substrate from the ingot; and
bonding the support substrate and the gallium nitride thin-film substrate by surface-activated bonding.

7. The manufacturing method according to claim 6, further comprising:
after bonding the support substrate and the gallium nitride thin-film substrate, growing an epitaxial layer including gallium nitride on the gallium nitride thin-film substrate, wherein
in preparing the ingot, the epitaxial layer is used as the ingot.
